(19) United States
(12) Patent Application Publication
(10) Pub. No.: US 2007/0178684 A1
(43) Pub. Date: Aug. 2, 2007

(54) Method for producing conductor arrays on semiconductor devices

(76) Inventors: Torsten Mueller, Dresden (DE); Josef Willer, Riemerling (DE); Stephanie Iacono, Dresden (DE)

Correspondence Address: SLATER & MATSIL LLP, 17950 PRESTON ROAD, SUITE 1000, DALLAS, TX, 75252, US

(21) Appl. No.: 11/344,961

(22) Filed: Jan. 31, 2006

(51) Int. Cl. H01L 21/44

(52) U.S. Cl. 438/597

(57) ABSTRACT

A periodic pattern of conductor tracks with broader interspaces is produced by the application of a totally periodic pattern and subsequent removal of individual conductor tracks. An alternative method comprises the formation of a completely periodic hardmask, from which individual parts are removed. The modified hardmask is then used to etch a periodic pattern of conductor tracks with intermediate broader spaces.

### TECHNICAL FIELD

The invention concerns a production method of conductor arrays, especially wordlines on memory devices, having a periodic pattern that is interrupted at equally spaced distances in order to provide an area in which inferior conducting layers can be contacted.

### BACKGROUND

Semiconductor memory devices comprise arrays of memory cells that are addressed individually. To this purpose, the memory cells are arranged as so-called cross-point cells, which are addressed by conductor tracks that are provided as wordlines and bitlines. All the wordlines are parallel to one another, and all the bitlines are parallel to one another and perpendicularly arranged with respect to the wordlines. The crossings of wordlines and bitlines define the locations of the memory cells. In order to reduce the necessary device area as far as possible, the dimensions of the memory cells are structured as small as possible. This results in extremely small distances between individual cells, which have to be addressed by the wordlines. Therefore, the wordlines must form an arrangement of conductor tracks that are equally spaced, in order to avoid short circuits between neighboring wordlines while the interspaces between the wordlines are as small as possible.

A very fine resolution can be achieved by photolithography techniques. It is possible to obtain a strictly periodic pattern of parallel conductor tracks by photolithography. On the other hand, the memory devices often require an application of contacts to buried bitlines in intermediate spaces between the wordlines. This means that the strictly periodic pattern of the wordlines has to be interrupted in order to provide contact areas between neighboring wordlines that are arranged at a greater distance than the wordlines in the periodic arrangement. The interruption of the strict periodicity causes problems with the photolithography, which may result in larger manufacturing tolerances of the periodic pattern. Therefore, deviations from the strict periodicity are avoided as much as possible.

### SUMMARY OF THE INVENTION

In one aspect, the present invention provides a method for producing periodic conductor arrays, especially on memory devices, which allows an insertion of broader interspaces between neighboring conductors.

In a further aspect, the invention provides a method for producing semiconductor memory devices comprising arrangements of parallel wordlines at minimal pitch, at the same time providing contact areas for the application of contacts on buried bitlines.

In a further aspect, the invention provides a periodic pattern of conductor tracks with periodic interruptions, in which the distance between neighboring wordlines is enhanced.

A first embodiment method includes the steps of providing a substrate with a main surface, applying an array of equally spaced conductor tracks onto the main surface, in order to form a periodic pattern of parallel conductor tracks, applying a mask onto the conductor tracks, which has openings to uncover isolated conductor tracks or small groups of two or a few neighboring conductor tracks, removing the uncovered conductor tracks by means of the mask, preferably by performing an etching step into said openings, and removing the mask.

In a variant of this method, a hardmask is structured according to the periodic pattern of the conductor tracks to be produced, a resist mask is applied, which covers the hardmask except in areas where the periodic pattern of the conductor tracks has to be interrupted by free spaces, the relevant individual parts of the hardmask are removed, the resist mask is removed, the hardmask is used to structure a layer of conductive material into the pattern of conductor tracks, and the hardmask is removed. The structuring of the hardmask can also be effected by means of a further hardmask of different material. For instance, a hardmask of nitride can be structured with a hardmask of amorphous silicon and vice versa. Principally, every material that is suitable for hardmasks can be applied here.

The conductor tracks can preferably be a metal or polysilicon that is doped to be electrically conductive. The conductor tracks can be provided for wordlines or bitlines. In preferred embodiments, the free spaces that are obtained by the removal of conductor tracks can be located at equal distances, so that the periodic pattern of conductor tracks is periodically interrupted. The width of the free intermediate spaces can be adjusted by the number of successive conductor tracks that are removed in each location of a free space.

These and other features and advantages of the invention, will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a plan view onto the periodic pattern of a hardmask, which is partially covered by a resist mask.

FIG. 2 shows the cross-section indicated in FIG. 1.

FIG. 3 shows a plan view onto a partially covered pattern of wordlines.

The following list of reference symbols can be used in conjunction with the figures:

1 substrate

2 buried bitline

3 layer of electrically conductive material

4 resist mask

5 lateral limit

6 hardmask

7 wordline

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

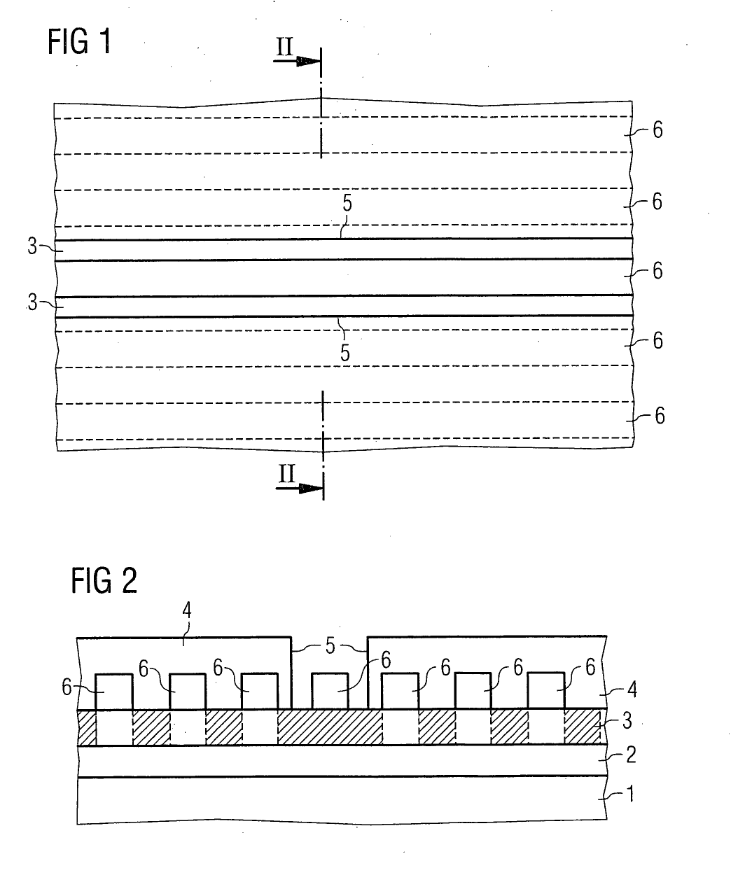

FIG. 1 shows a plan view onto a main surface of a substrate, which is provided with a hardmask 6, which is patterned according to a periodic pattern of conductor tracks. The hardmask is partially covered by a resist mask 4, of which the lateral limits 5 are shown in FIG. 1. A layer 3 of electrically conductive material is shown in the opening of the resist mask 4 on both sides of one part of the hardmask 6, which is uncovered by the opening of the resist. The covered parts of the hardmask 6 are shown with broken lines as concealed contours.

FIG. 2 shows the cross-section indicated in FIG. 1, taken transversely to the longitudinal extension of the hardmask 6. For the sake of an example, FIG. 2 shows a substrate 1, a buried bitline 2, which is formed at a main surface of the substrate 1, a layer 3 of electrically conductive material, which is applied onto the main surface, and the hardmask 6, which is structured according to the conductor tracks to be produced into individual parts of a striplike shape. The resist mask 4 has at least one opening with lateral limits 5 in the area of at least one of the separate portions of the hardmask 6. The resist mask 4 enables the removal of the uncovered part or parts of the hardmask 6. This renders an interruption of the strictly periodic pattern of the hardmask 6. In this way, it is possible to obtain an extremely fine periodic pattern and at the same time to provide interruptions of the periodicity to form broader interspaces between neighboring parts of the hardmask 6 in especially selected areas. After the hardmask 6 has been removed in the openings of the resist mask 4, the resist mask 4 is removed, and the layer 3 can be structured by means of the hardmask 6. In the example shown in FIG. 2, the parts of the layer 3 that are located in the hatched regions are removed. This can be done by a standard anisotropic etching process. The hardmask 6 is then removed, and the layer 3 remains structured according to a strictly periodic pattern, which is interrupted in selected areas. These selected areas corresponding to the openings of the resist mask 4, are preferably spaced apart at equal distances and can be used to apply contacts on the buried bitlines 2 underneath.

It is also possible, to use the original periodic hardmask to form a completely periodic pattern of conductor tracks. The broader interspaces are then produced by means of a mask, which is applied to the arrangement of conductor tracks and which has openings above individual conductor tracks, small groups of neighboring conductor tracks or both, possibly in varying succession. This mask is then used to remove single ones or small groups of the conductor tracks, in the areas in which interspaces between neighboring conductor tracks have to be provided to enable the application of contacts to inferior layers.

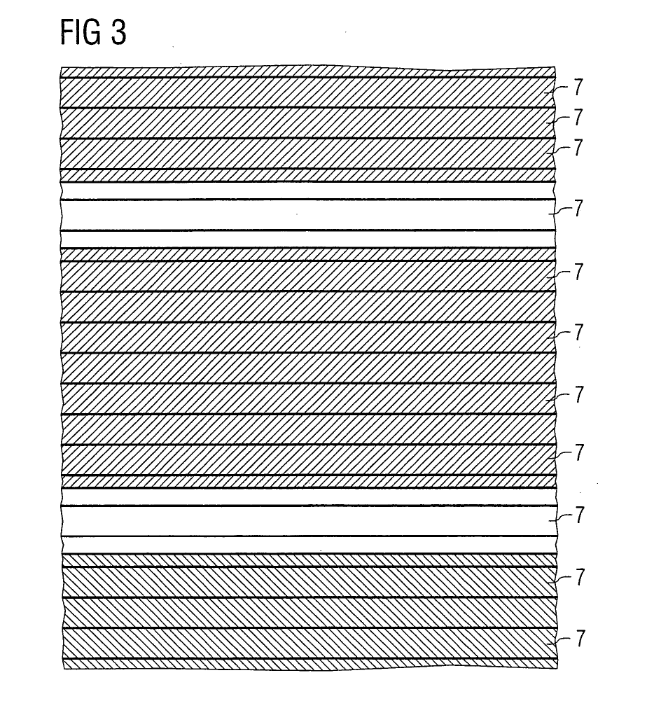

FIG. 3 shows a plan view onto a periodic arrangement of wordlines 7, which are equally spaced apart. In the special example shown in FIG. 3, both the widths of the wordlines 7 and the widths of the interspaces are the same. Instead, the wordlines 7 can be broader than the interspaces or vice versa. The areas that are hatched in FIG. 3 are covered by a resist mask 4, which has openings above single wordlines in this example. These openings can especially be situated at equal distances from one another. The mask is used to remove the uncovered wordlines, thus forming interspaces, which provide an area in which contacts or vias can be applied. The spaces between the wordlines, including the broader interspaces, can then be filled with dielectric material, for example with TEOS (tetraethylorthosilicate) or BPSG (boron phosphorus silicate glass). This method is especially favorable to produce spaces for bitline contacts between the wordlines. This is achieved by removing wordlines from a regular array, instead of providing interspaces of varying width in a straightforward way already by the lithography step. Since the wordline array is not interrupted in the first lithography step, additional means, like dummy lines or scatter bars, are not required. The process window is essentially increased without compromising the chip size.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of producing conductor arrays on semiconductor devices, the method comprising:
providing a substrate having a main surface;
forming an array of conductor tracks in a periodic pattern over the main surface;
forming a mask over the conductor tracks, the mask leaving uncovered a plurality of said conductor tracks of the group consisting of:
a) a plurality of single ones of said conductor tracks, these single conductor tracks being separated from one another by covered ones of said conductor tracks;
b) a plurality of groups of at least two neighboring ones of said conductor tracks, these groups being separated from one another by covered ones of said conductor tracks; and
c) a plurality of single ones of said conductor tracks and groups of at least two neighboring ones of said conductor tracks, these single conductor tracks and groups being separated from one another by covered ones of said conductor tracks;
removing the conductor tracks that are not covered by said mask; and
removing said mask.

2. The method according to claim 1, wherein forming an array of conductor tracks comprises forming metal tracks.

3. The method according to claim 1, wherein forming an array of conductor tracks comprises forming doped polysilicon tracks.

4. A method of producing conductor arrays on semiconductor devices, the method comprising:
providing a substrate having a main surface;
forming an array of periodically arranged parallel conductor tracks on said main surface; and
removing at least one of said conductor tracks while leaving neighboring ones of said at least one conductor track.

5. The method according to claim 4, wherein forming an array of conductor tracks comprises forming metal tracks.

6. The method according to claim 4, wherein forming an array of conductor tracks comprises forming doped polysilicon tracks.

7. A method of producing conductor arrays on semiconductor devices, the method comprising:
providing a substrate having a main surface;
forming an array of periodically arranged parallel conductor tracks on said main surface; and
removing at least a group of neighboring ones of said conductor tracks while conductor tracks that are next to said group remain.

8. The method according to claim 7, wherein forming an array of conductor tracks comprises forming metal tracks.

9. The method according to claim 7, wherein forming an array of conductor tracks comprises forming doped polysilicon tracks.

10. A method of producing conductor arrays on semiconductor devices, the method comprising:
providing a semiconductor chip with a periodic pattern of conductor tracks; and
removing isolated ones of said conductor tracks to interrupt the periodic pattern by interspaces.

11. The method according to claim 10, wherein the interspaces are at equal distances from one another in areas in which conductor tracks are removed.

12. The method according to claim 10, wherein providing a semiconductor chip comprises providing said conductor tracks as wordlines of an array of memory cells; and providing further conductors below said wordlines, the method further comprising applying contacts to said further conductors in said interspaces.

13. A method of producing conductor arrays on semiconductor devices, the method comprising:
providing a semiconductor chip with a periodic pattern of conductor tracks; and
removing groups of said conductor tracks, said groups being separated by further ones of said conductor tracks, to interrupt the periodic pattern by interspaces.

14. The method according to claim 13, wherein the interspaces are at equal distances from one another in areas in which conductor tracks are removed.

15. The method according to claim 13, wherein providing a semiconductor chip comprises providing said conductor tracks as wordlines of an array of memory cells; and providing further conductors below said wordlines, the method further comprising applying contacts to said further conductors in said interspaces.

16. A method of producing conductor arrays on semiconductor devices, the method comprising:
providing a semiconductor chip with a main surface;
forming at least one layer of electrically conductive material on said main surface;
forming a hardmask onto said layer;
structuring said hardmask periodically according to a periodic pattern of conductor tracks;
removing at least one isolated part of the structured hardmask, thus interrupting the periodic pattern;
removing portions of said layer of electrically conductive material that are not covered by the hardmask, thus forming an array of conductor tracks in an interrupted periodic pattern; and
removing the hardmask.

17. The method according to claim 16, wherein forming at least one layer of electrically conductive material comprises forming at least one layer of a metal.

18. The method according to claim 16, wherein forming at least one layer of electrically conductive material comprises forming at least one layer of doped polysilicon.

19. The method according to claim 16, wherein forming at least one layer of electrically conductive material comprises forming at least one layer of electrically conductive material as a part of a layer sequence that is provided for wordline stacks.

20. The method according to claim 16, wherein forming a hardmask comprises forming a nitride hardmask.

21. The method according to claim 16, wherein forming a hardmask comprises forming an amorphous silicon hardmask.

22. The method according to claim 16, wherein removing at least one isolated part of the structured hardmask comprises removing portions of the structured hardmask that are equally spaced apart.

23. The method according to claim 16, wherein removing at least one isolated part of the structured hardmask comprises removing portions of the structured hardmask in areas that are provided for contacts of buried bitlines.

24. The method according to claim 16, further comprising filling spaces between the conductor tracks with dielectric material.

25. A method of producing conductor arrays on semiconductor devices, the method comprising:
providing a semiconductor chip with a main surface;
forming at least one layer of electrically conductive material on said main surface;
forming a first mask onto said layer;
structuring said first mask periodically according to a periodic pattern of conductor tracks;
forming a second mask onto said first mask;
removing portions of said first mask by means of said second mask, thus interrupting the periodic pattern;
removing said second mask;
removing portions of said layer of electrically conductive material in alignment with the first mask, thus forming an array of conductor tracks in an interrupted periodic pattern; and
removing said first mask.

26. The method according to claim 25, wherein the first mask comprises a hardmask and wherein the second mask also comprises a hardmask.

27. The method according to claim 26, wherein the first mask is formed from nitride and the second mask is formed from amorphous silicon.

28. The method according to claim 26, wherein the second mask is formed from nitride and the first mask is formed from amorphous silicon.
